(19) United States
(12) Patent Application Publication
(10) Pub. No.: US 2025/0291245 A1
(43) Pub. Date: Sep. 18, 2025

(54) RESIST COMPOSITION AND PATTERN FORMING PROCESS

(71) Applicant: Shin-Etsu Chemical Co., Ltd., Tokyo (JP)

(72) Inventors: Masaki Ohashi, Joetsu-shi (JP); Shun Kikuchi, Joetsu-shi (JP); Ryunosuke Handa, Joetsu-shi (JP); Satoshi Kusama, Joetsu-shi (JP)

(73) Assignee: Shin-Etsu Chemical Co., Ltd., Tokyo (JP)

(21) Appl. No.: 19/073,393

(22) Filed: Mar. 7, 2025

(30) Foreign Application Priority Data
Mar. 13, 2024 (JP) 2024-038566

(51) Int. Cl. G03F 7/004; G03F 7/00; G03F 7/039; G03F 7/32

(52) U.S. Cl. CPC G03F 7/0042; G03F 7/0397; G03F 7/322; G03F 7/70033

(57) ABSTRACT

The non-chemically amplified resist composition exhibits a high sensitivity and resolution when processed by photolithography using high-energy radiation, typically electron beam (EB) lithography and EUV lithography. The resist composition can be applicable for forming a pattern forming process. The resist composition comprises a hypervalent bismuth compound, a carboxylic acid, and a solvent.

### CROSS-REFERENCE TO RELATED APPLICATIONS

This non-provisional application claims priority under 35 U.S.C. § 119 (a) on Patent Application No. 2024-038566 filed in Japan on Mar. 13, 2024, the entire contents of which are hereby incorporated by reference.

TECHNICAL FIELD

This invention relates to a resist composition and a pattern forming process.

BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation extreme ultraviolet (EUV) lithography of wavelength 13.5 nm.

As the feature size is reduced, image blurs due to acid diffusion become a problem (see Non-Patent Document 1). To insure resolution for fine patterns with a processing dimension of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having polymerizable olefin. With respect to the patterning of a resist film to a processing dimension of 16 nm et seq., it is believed impossible in the light of acid diffusion to form such a pattern from a chemically amplified resist composition. It would be desirable to have a non-chemically amplified resist composition.

A typical material for non-chemically amplified resist composition is polymethyl methacrylate (PMMA). PMMA is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than or equal to half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of a practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing iodine atoms. However, as mentioned above, the chemically amplified resist composition cannot reach the resolution desired in the EUV lithography where the processing dimension becomes smaller than ever.

Patent Document 2 discloses a negative resist composition comprising a tin compound. Based on tin element having high EUV absorption, this resist composition is improved in stochastics and achieves a high sensitivity and high resolution. Such so-called metal resist compositions, however, suffer from many problems including low solubility in resist solvents, poor shelf stability due to excessively high reactivity, and defectiveness due to post-etching residues.

### CITATION LIST

Patent Document 1: JP-A 2018-5224
Patent Document 2: JP-A 2021-503482
Non-Patent Document 1: SPIE Vol. 5039 p1 (2003)
Non-Patent Document 2: SPIE Vol. 6520 p65203L-1 (2007)

### SUMMARY OF THE INVENTION

An object of the invention is to provide a non-chemically amplified resist composition which exhibits a high sensitivity and resolution when processed by photolithography using high-energy radiation, typically electron beam (EB) lithography and EUV lithography, and a pattern forming process using the resist composition.

The inventors have found that a resist composition based on a specific bismuth compound and a carboxylic acid has a very high sensitivity, forms a resist film having a satisfactory resolution, and is thus quite useful in precise micropatterning.

The invention provides a resist composition and a pattern forming process described below.
1. A resist composition comprising a hypervalent bismuth compound, a carboxylic acid, and a solvent.
2. The resist composition of the item 1 wherein the hypervalent bismuth compound has formula (1):

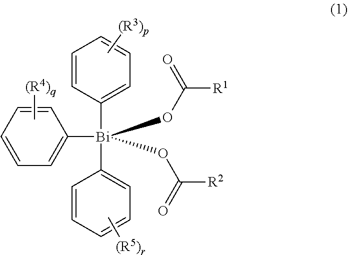

wherein p, q, and r are each independently an integer of 0 to 5,

R¹ and R² are each independently halogen or a C₁-C₁₀ hydrocarbyl group which may contain a heteroatom, R¹ and R² may bond together to form a ring with the carbon atoms to which they are attached and the intervenient atoms, and

R³, R⁴, and R⁵ are each independently halogen or a C₁-C₄₀ hydrocarbyl group which may contain a heteroatom.
3. The resist composition of the item 1 or 2 wherein the carboxylic acid has formula (2):

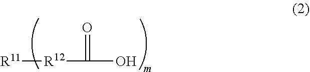

wherein m is an integer of 1 to 4,

R¹¹ is a C₁-C₄₀ m-valent hydrocarbon group or C₂-C₄₀ m-valent heterocyclic group, when m is 2, R¹¹ may be an ether bond, carbonyl group, azo group, thioether bond, carbonate bond, carbamate bond, sulfinyl group or sulfonyl group, and some or all of the hydrogen atoms in the m-valent hydrocarbon group or m-valent heterocyclic group may be substituted by a heteroatom-containing moiety, and some constituent —CH₂— in the m-valent hydrocarbon group may be substituted by a heteroatom-containing moiety,

R¹² is a single bond or C₁-C₁₀ hydrocarbylene group, and some or all of the hydrogen atoms in the hydrocarbylene group may be substituted by a heteroatom-containing moiety, some constituent −CH₂— in the hydrocarbylene group may be substituted by a heteroatom-containing moiety, and when m is an integer of 2 to 4, a plurality of R¹² may be the same or different.
4. A pattern forming process comprising the steps of applying the resist composition of any one of the items 1 to 3 onto a substrate to form a resist film thereon, exposing the resist film to high-energy radiation, and developing the exposed resist film in a developer.
5. The pattern forming process of the item 4 wherein the high-energy radiation is EB or EUV.
6. The pattern forming process of the item 4 or 5 wherein the developer dissolves an exposed portion and does not dissolve an unexposed portion.
7. The pattern forming process of the item 4 or 5 wherein the developer dissolves an unexposed portion and does not dissolve an exposed portion.

### ADVANTAGEOUS EFFECTS OF THE INVENTION

The resist composition exhibits both high sensitivity and resolution when processed by EB and EUV lithography and is quite useful in micropatterning.

### DETAILED DESCRIPTION OF THE INVENTION

### [Resist Composition]

One embodiment of the invention is a resist composition based on a hypervalent bismuth compound and a carboxylic acid.

### [Hypervalent Bismuth Compound]

The hypervalent bismuth compound is a general term for bismuth compounds having valence electrons beyond the octet rule formally. Examples of the hypervalent bismuth compound include five-coordinate bismuth compounds having an oxidation number of +5.

The preferred hypervalent bismuth compound is a five-coordinate hypervalent bismuth compound having formula (1).

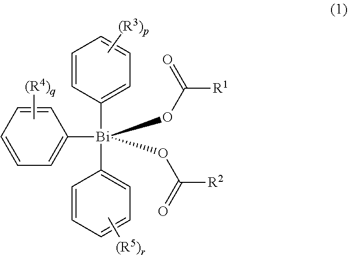

In formula (1), p, q, and r are each independently an integer of 0 to 5.

In formula (1), R¹ and R² are each independently halogen or a C₁-C₁₀ hydrocarbyl group which may contain a heteroatom. Also, R¹ and R² may bond together to form a ring with the carbon atoms to which they are attached and the intervenient atoms. Specific examples of the halogen atoms include fluorine, chlorine, bromine and iodine. The C₁-C₁₀ hydrocarbyl group may be saturated or unsaturated and straight, branched or cyclic. Examples thereof include C₁-C₁₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl, C₂-C₁₀ alkenyl groups such as vinyl and allyl, C₆-C₁₀ aryl groups such as phenyl and naphthyl, and combinations thereof. Also included are hydrocarbyl groups in which some or all of the hydrogen atoms may be substituted by a moiety containing a heteroatom such as oxygen, sulfur, nitrogen, or halogen, and some constituent —CH₂— may be substituted by a moiety containing a heteroatom such as oxygen, sulfur, or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ and R² are preferably C₁-C₄ hydrocarbyl groups.

In formula (1), R³, R⁴, and R⁵ are each independently halogen or a C₁-C₄₀ hydrocarbyl group which may contain a heteroatom. Specific examples of the halogen atoms include fluorine, chlorine, bromine and iodine. The C₁-C₄₀ hydrocarbyl group may be saturated or unsaturated and straight, branched or cyclic. Examples thereof include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl; and C₆-C₄₀ aryl groups such as phenyl, naphthyl, and anthracenyl. Also included are hydrocarbyl groups in which some or all of the hydrogen atoms may be substituted by a moiety containing a heteroatom such as oxygen, sulfur, nitrogen, or halogen, and some constituent —CH₂— may be substituted by a moiety containing a heteroatom such as oxygen, sulfur, or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). When p is an integer of 2 to 5, a plurality of R³ may be the same or different, when q is an integer of 2 to 5, a plurality of R⁴ may be the same or different, and when r is an integer of 2 to 5, a plurality of R⁵ may be the same or different.

Specific examples of the hypervalent bismuth compound having formula (1) are shown below, but not limited thereto.

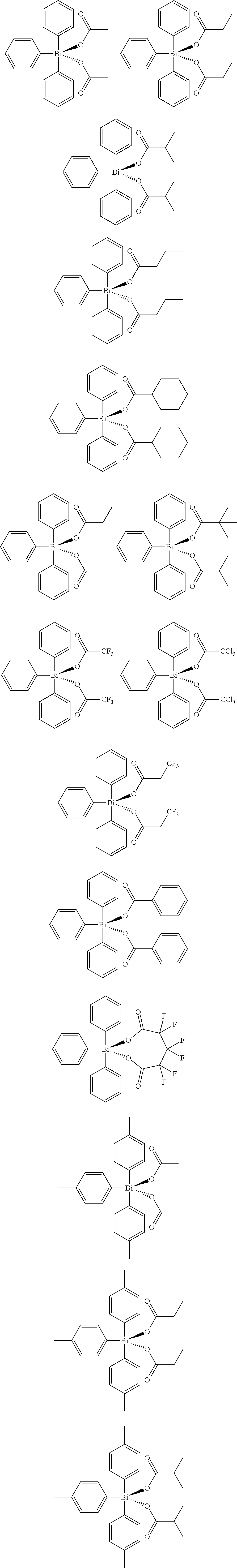

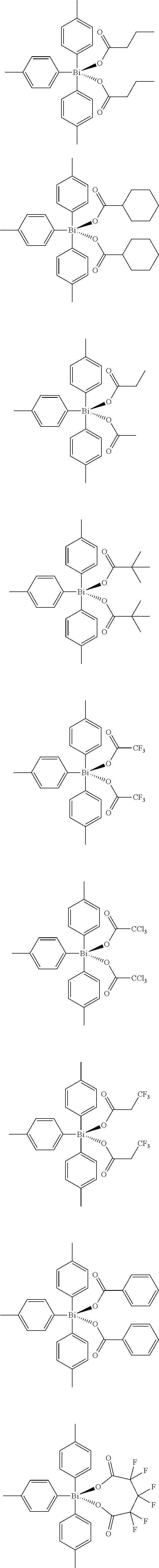

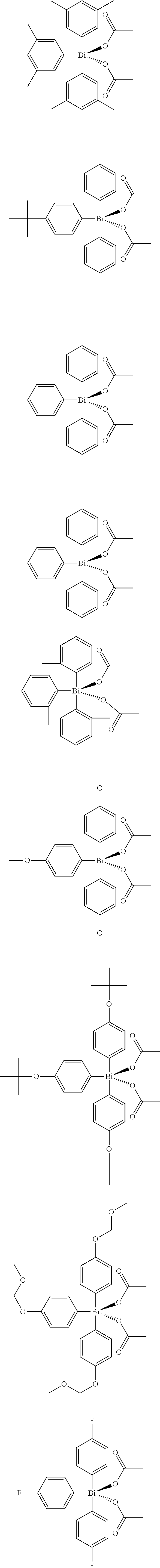

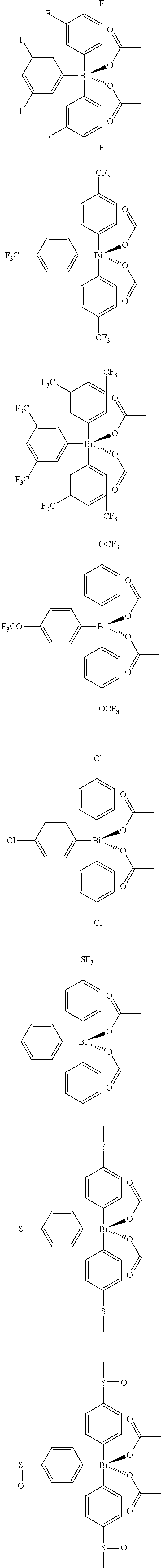

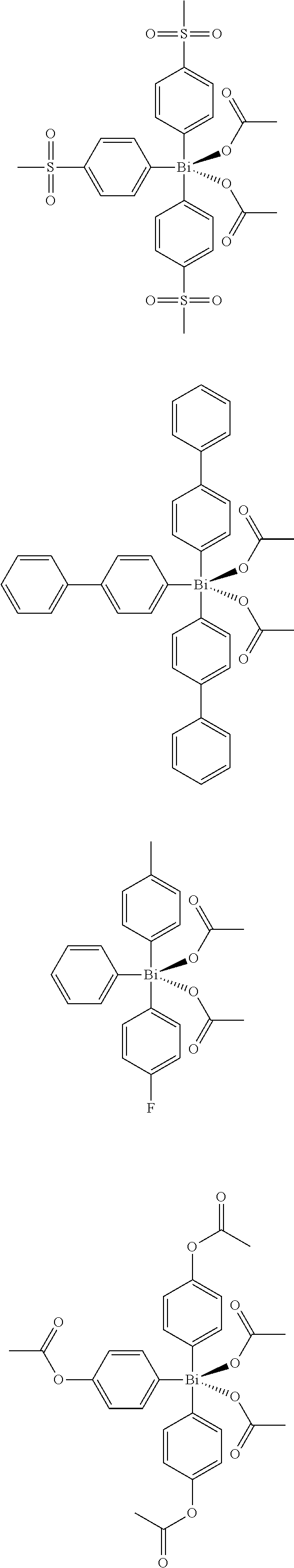

### [Carboxylic Acid]

As the carboxylic acid used herein, all compounds which are generally defined as carboxylic acid in the organic chemistry field are applicable. A carboxylic acid having formula (2) is preferred.

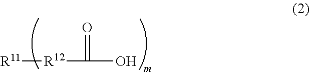

In formula (2), m is an integer of 1 to 4. R¹¹ is a C₁-C₄₀ m-valent hydrocarbon group or C₂-C₄₀ m-valent heterocyclic group, when m is 2, R¹¹ may be an ether bond, carbonyl group, azo group, thioether bond, carbonate bond, carbamate bond, sulfinyl group or sulfonyl group, and some or all of the hydrogen atoms in the m-valent hydrocarbon group or m-valent heterocyclic group may be substituted by a heteroatom-containing moiety, and some constituent —CH₂— in the m-valent hydrocarbon group may be substituted by a heteroatom-containing moiety, R¹² is a single bond or C₁-C₁₀ hydrocarbylene group, and some or all of the hydrogen atoms in the hydrocarbylene group may be substituted by a heteroatom-containing moiety, and some constituent —CH₂— in the hydrocarbylene group may be substituted by a heteroatom-containing moiety, and when m is an integer of 2 to 4, a plurality of R¹² may be the same or different.

The m-valent hydrocarbon group represented by R¹¹ may be saturated or unsaturated and straight, branched or cyclic. The m-valent hydrocarbon group is obtained by removing m number of hydrogen atoms from a hydrocarbon. Specific examples of the hydrocarbon include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Specific examples of the C₁-C₄₀ alkanes include methane, ethane, propane, butane, pentane, hexane, heptane, octane, nonane, decane, and structural isomers thereof.

Specific examples of the C₂-C₄₀ alkenes include ethylene, propylene, butene, pentene, hexene, heptene, octene, nonene, decene, and structural isomers thereof.

Specific examples of the C₂-C₄₀ alkynes include acetylene, propyne, butyne, pentyne, hexyne, heptyne, octyne, nonyne, decyne, and structural isomers thereof.

Specific examples of the C₃-C₄₀ cyclic saturated hydrocarbons include cyclopropane, cyclobutane, cyclohexane, cycloheptane, cyclooctane, adamantane, and norbornane.

Specific examples of the C₃-C₄₀ cyclic unsaturated hydrocarbons include cyclopropene, cyclobutene, cyclopentene, cyclohexene, cycloheptene, cyclooctene, and norbornene.

Specific examples of the C₆-C₄₀ aromatic hydrocarbons include benzene, naphthalene, and biphenyl.

The m-valent heterocyclic group represented by R¹¹ is obtained by removing m number of hydrogen atoms from a heterocyclic compound. Specific examples of the heterocyclic compounds include furane, pyridine, pyrazole, and thiazolidine.

In the m-valent hydrocarbon group and m-valent heterocyclic group, some or all of the hydrogen atoms may be substituted by a moiety containing a heteroatom such as oxygen, sulfur, nitrogen or halogen, so that the group may contain hydroxy, cyano, fluorine, chlorine, bromine, or iodine. In the m-valent hydrocarbon group, some constituent —CH₂— may be substituted by a moiety containing a heteroatom such as oxygen, sulfur or nitrogen, so that the group may contain carbonyl, ether bond, thioether bond, ester bond, sulfonic ester bond, carbonate bond, carbamate bond, lactone ring, sultone ring, or carboxylic anhydride (—C(═O)—O—C(═O)—).

The hydrocarbylene group represented by R¹² may be saturated or unsaturated and straight, branched or cyclic. Specific examples thereof include C₁-C₂₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, and dodecane-1,12-diyl, C₃-C₂₀ cyclic saturated hydrocarbylene groups such as cyclopentanediyl, cyclohexanediyl, norbornanediyl, and adamantanediyl, C₂-C₂₀ unsaturated aliphatic hydrocarbylene groups such as vinylene and propene-1,3-diyl, C₆-C₂₀ arylene groups such as phenylene and naphthylene, and combinations thereof. In the hydrocarbylene group, some or all of the hydrogen atoms may be substituted by a moiety containing a heteroatom such as oxygen, sulfur, nitrogen or halogen, and some constituent —CH₂— may be substituted by a moiety containing a heteroatom such as oxygen, sulfur or nitrogen, so that the group may contain hydroxy, cyano, fluorine, chlorine, bromine, iodine, carbonyl, ether bond, thioether bond, ester bond, sulfonic ester bond, carbonate bond, carbamate bond, lactone ring, sultone ring, or carboxylic anhydride (—C(═O)—O—C(═O)—).

Specific examples of the carboxylic acid are shown below, but not limited thereto.

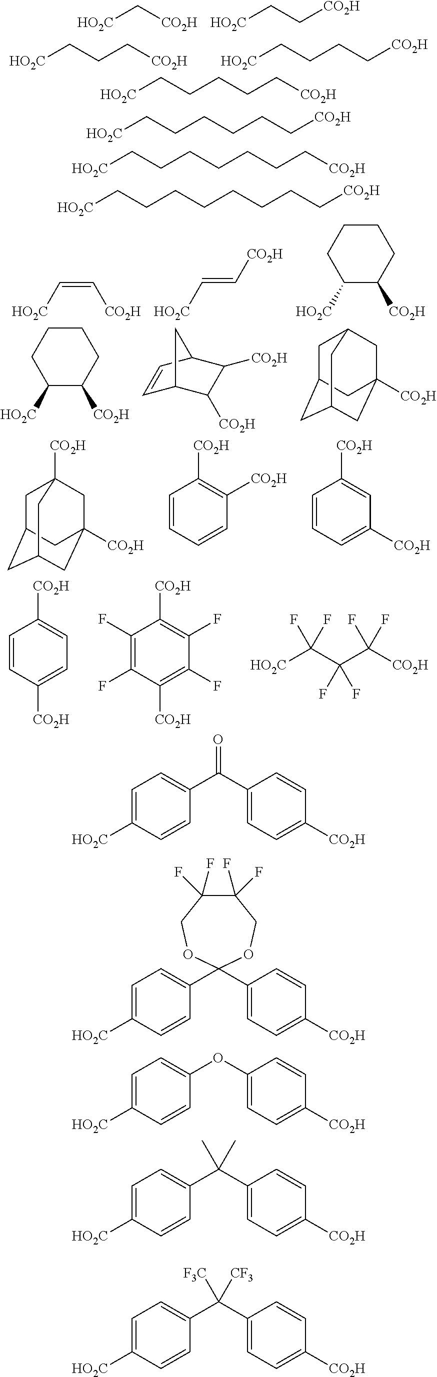

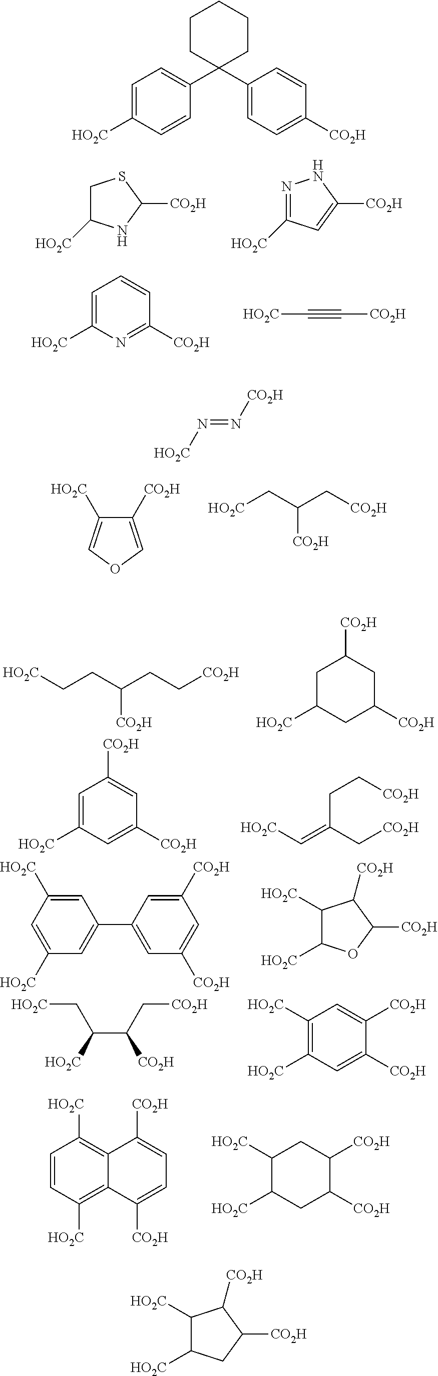

In the resist composition, the hypervalent bismuth compound and the carboxylic acid are preferably present in a molar ratio of from 10:90 to 90:10, more preferably from 20:80 to 80:20, even more preferably from 30:70 to 70:30.

### [Solvent]

The resist composition contains a solvent. The solvent is not particularly limited as long as the hypervalent bismuth compound, the carboxylic acid, and other components described below are dissolvable therein and a film can be formed from the resulting solution. The solvent is preferably an organic solvent, and specific examples of the organic solvent include ketones such as cyclohexanone, methyl-2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono tert-butyl ether acetate; carboxylic acids such as formic acid, acetic acid, and propionic acid, lactones such as y-butyrolactone, and mixtures thereof.

In the resist composition, the solvent is preferably present in such amounts that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent. The solvents may be used alone or in admixture of two or more.

### [Other Components]

The resist composition may further contain a surfactant. The surfactant is preferably a fluorine-based and/or silicone-based surfactant. Specific examples of such surfactants are described, for example, in US 2008/0248425, paragraph [0276]. Also useful are surfactants other than the fluorine-based and/or silicone-based surfactants, as described, for example, in US 2008/0248425, paragraph [0280].

When the resist composition contains the surfactant, the surfactant is preferably present in an amount of 0.0001 to 2% by weight based on the overall solids. The surfactant may be used alone or in admixture of two or more.

The resist composition may further contain a radical scavenger. When added, the radical scavenger is effective for controlling photo-reaction and adjusting sensitivity during photolithography.

Specific examples of the radical scavenger include hindered phenols, quinones, hindered amines, and thiol compounds. Specific examples of the hindered phenols include dibutylhydroxytoluene (BHT) and 2,2′-methylenebis (4-methyl-6-tert-butylphenol). Specific examples of the quinones include 4-methoxyphenol (or methoquinone) and hydroquinone. Specific examples of the hindered amines include 2,2,6,6-tetramethylpyperidine and 2,2,6,6-tetramethylpyperidine-N-oxy radical. Specific examples of the thiol compounds include dodecanethiol and hexadecanethiol.

When the resist composition contains the radical scavenger, the radical scavenger is preferably present in an amount of 0.01 to 10% by weight based on the overall solids. The radical scavenger may be used alone or in admixture of two or more.

The resist composition contains the hypervalent bismuth compound and the carboxylic acid as main components, but not a base polymer containing an acid labile group and a photoacid generator as used in conventional chemically amplified resist compositions. Nevertheless, in the resist composition, solubility of the developer is changed in the unexposed portion and the exposed portion particularly by EB or EUV exposure, and a pattern can be formed. Although its mechanism is not well understood, the following mechanism is presumed.

The hypervalent bismuth compound is a five-coordinate compound having bonded thereto an aryl group and two carboxylate ligands as represented by formula (1). When such a five-coordinate bismuth compound is mixed with a carboxylic acid, replacement of carboxylate ligands takes place as equilibration reaction. If the original carboxylate ligands are removed by any suitable means, a hypervalent bismuth compound having new ligands is created. For example, if triphenylbismuth diacetate, which is relatively readily available as the hypervalent bismuth compound, is mixed with a carboxylic acid having a high molecular weight, and the resulting low-boiling acetic acid is removed, then ligand exchange is completed. If the ligand has a fully high molecular weight, then a robust resist film is formed. Particularly when the carboxylic acid has a plurality of carboxy groups (for example, a dicarboxylic acid) is used, a high molecular weight compound of polyester structure having the hypervalent bismuth compound is formed. This ensures film formability.

The combined form of hypervalent bismuth compound and carboxylic acid is formed during film preparation. That is, by removing a low-molecular-weight carboxylic acid during film formation and subsequent bake step, ligand exchange reaction is completed and a resist film is formed.

The formed hypervalent bismuth compound is decomposed by light to change the polarity, and a pattern is formed by the development step. Note that a positive or negative pattern can be formed by appropriately selecting a developer.

From the foregoing presumption, the inventive resist composition is a non-chemically amplified resist composition. Using the inventive resist composition, a small size pattern can be resolved without image blur due to acid diffusion as found in conventional chemically amplified resist compositions (i.e., compositions comprising a base polymer and a photoacid generator).

The inventive resist composition is quite effective in the EUV lithography. This is because a bismuth atom having a high absorptivity to EUV radiation is included. That is, shot noise is reduced, and higher resolution and lower LWR are achievable.

As the EUV lithography resist composition capable of forming a small size pattern, a metal resist composition based on a metal (specifically tin) compound having a high absorptivity to EUV radiation like bismuth atom is known, for example, from Patent Document 2. However, the metal resist composition suffers from many problems including a lack of solvent solubility, poor shelf stability, and the like. In contrast, the inventive resist composition is excellent in solvent solubility. Furthermore, since the inventive resist composition can be applied to either a positive or a negative resist, the resist composition has a wide range of use applications. For example, in the contact hole forming step, in the metal resist composition as conducted in negative tone development, the reversal processing step is required after the formation of the pillar pattern, but in the positive resist, such a step is unnecessary. Therefore, from the viewpoint of process simplicity, the inventive resist composition is regarded more useful than the metal resist composition.

### [Pattern Forming Process]

When the resist composition is used in the fabrication of various integrated circuits, any well-known lithography techniques are applicable. For example, specific examples of the pattern forming process comprise the steps of applying the resist composition onto a substrate to form a resist film thereon, exposing the resist film to high-energy radiation, and developing the exposed resist film in a developer.

First, the resist composition is applied onto a substrate for integrated circuit fabrication (e.g., Si, SiO₂, SiN, SiON, TiN, WSi, BPSG, SOG, or organic antireflective coating) or a substrate for mask circuit fabrication (e.g., Cr, CrO, CrON, MoSi₂, or SiO₂) by any suitable technique such as spin coating, roll coating, flow coating, dip coating, spray coating or doctor coating to form a resist film having a thickness of 0.01 to 2 μm. The coating is prebaked on a hot plate at a temperature of preferably 60 to 200° C. for 10 seconds to 30 minutes, more preferably at 80 to 180° C. for 30 seconds to 20 minutes to form a resist film.

Next the resist film is exposed to high-energy radiation. Specific examples of the high-energy radiation is selected from among UV, FUV, EB, EUV, X-ray, soft X-ray, excimer laser radiation, γ-ray, and synchrotron radiation. On use of UV, FUV, EUV, X-ray, soft X-ray, excimer laser radiation, γ-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 5000 μC/cm², more preferably about 0.5 to 4000 μC/cm². The resist composition is best suited in micropatterning using EB or EUV as the high-energy radiation.

If necessary, the resist film is post-exposure baked (PEB). At this time, preferably PEB is performed on a hot plate or in an oven at 30 to 120° C. for 10 seconds to 30 minutes, more preferably at 60 to 100° C. for 30 seconds to 20 minutes.

After the exposure or PEB, the resist film is developed in a developer to form a pattern. Specific examples of the organic solvent used as the developer is preferably selected from an aqueous alkali solution such as an aqueous tetramethylammonium hydroxide solution, 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, n-butanol, n-pentanol, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, diacetone alcohol, and 4-methyl-2-pentanol. In the practice of the invention, a positive pattern that dissolves the exposed portion and does not dissolve the unexposed portion is formed by organic solvent development, and a negative pattern that dissolves the unexposed portion and does not dissolve the exposed portion is formed by alkaline aqueous solution development. These developers may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Water may be used as the rinsing liquid instead of the organic solvent.

Rinsing is effective for preventing the resist pattern from collapse or reducing defect formation. Rinsing is not essential. By omitting rinsing, the amount of the solvent used is saved.

### EXAMPLES

Examples and Comparative Examples of the invention are given below by way of illustration and not by way of limitation.

### [1] Preparation of Resist Composition

### Examples 1-1 to 1-16 and Comparative Examples 1-1 to 1-3

Resist compositions (R-01 to R-16) were prepared by dissolving a hypervalent bismuth compound and a carboxylic acid in a solvent in accordance with the recipe shown in Table 1, and filtering the solution through a Teflon® filter having a pore size of 0.2 μm. Separately, comparative resist compositions (CR-01 to CR-03) were prepared by mixing a polymer, a photoacid generator, a sensitivity modifier, a solvent, and 0.01% by weight of a surfactant (PF-636, manufactured by OMNOVA Solutions Inc.) in accordance with the recipe shown in Table 2, and filtering the solution through a Teflon® filter having a pore size of 0.2 μm.

| | | | Hypervalent | | | |
|---|---|---|---|---|---|---|
| | | Resist | bismuth | Carboxylic | | |
| | | com- | compound | acid | Solvent 1 | Solvent 2 |
| | | position | (pbw) | (pbw) | (pbw) | (pbw) |
| Ex- | 1-1 | R-01 | B-1 (14.0) | CA-1 (9.0) | PGMEA (900) | GBL (100) |
| am- | 1-2 | R-02 | B-1 (14.0) | CA-2 (3.0) | PGMEA (900) | GBL (100) |
| ple | 1-3 | R-03 | B-1 (14.0) | CA-3 (2.9) | PGMEA (900) | GBL (100) |
| | 1-4 | R-04 | B-1 (14.0) | CA-4 (3.7) | PGMEA (900) | GBL (100) |
| | 1-5 | R-05 | B-1 (14.0) | CA-5 (4.2) | PGMEA (900) | GBL (100) |
| | 1-6 | R-06 | B-1 (14.0) | CA-6 (6.0) | PGMEA (1000) | — |
| | 1-7 | R-07 | B-1 (14.0) | CA-7 (6.0) | PGMEA (1000) | — |
| | 1-8 | R-08 | B-1 (14.0) | CA-8 (2.9) | PGMEA (900) | GBL (100) |
| | 1-9 | R-09 | B-1 (14.0) | CA-9 (9.8) | HBM (1000) | — |
| | 1-10 | R-10 | B-1 (14.0) | CA-10 (3.6) | PGMEA (900) | GBL (100) |
| | 1-11 | R-11 | B-1 (14.0) | CA-11 (3.7) | PGMEA (900) | GBL (100) |
| | 1-12 | R-12 | B-2 (15.4) | CA-9 (9.8) | PGMEA (1000) | — |
| | 1-13 | R-13 | B-3 (18.2) | CA-6 (6.0) | PGMEA (1000) | — |
| | 1-14 | R-14 | B-1 (16.8) | CA-4 (3.7) | PGMEA (900) | GBL (100) |
| | 1-15 | R-15 | B-1 (14.0) | CA-4 (4.4) | PGMEA (900) | GBL (100) |
| | 1-16 | R-16 | B-1 (7.0) | CA-6 (6.0) | HBM (1000) | — |
| | | | B-2 (7.7) | | | |

TABLE 2

| | | Resist | Base | Photoacid | Sensitivity | | Solvent |
|---|---|---|---|---|---|---|---|
| | | com | polymer | generator | modifier | Solvent 1 | 2 |
| | | position | (pbw) | (pbw) | (pbw) | (pbw) | (pbw) |
| Com- | 1-1 | CR-01 | P-1 (80) | PAG-1 (19.0) | Q-1 (6.2) | PGMEA | GBL |
| par- | | | | | | (1890) | (210) |
| ative | 1-2 | CR-02 | P-1 (80) | PAG-2 (21.0) | Q-1 (6.2) | PGMEA | GBL |
| Exam- | | | | | | (1890) | (210) |
| ple | 1-3 | CR-03 | P-1 (80) | PAG-1 (19.0) | Q-2 (2.6) | PGMEA | GBL |
| | | | | | | (1890) | (210) |

In Table 1, the hypervalent bismuth compounds (B-1 to B-3), the carboxylic acids (CA-1 to CA-11), and the solvent are identified below.

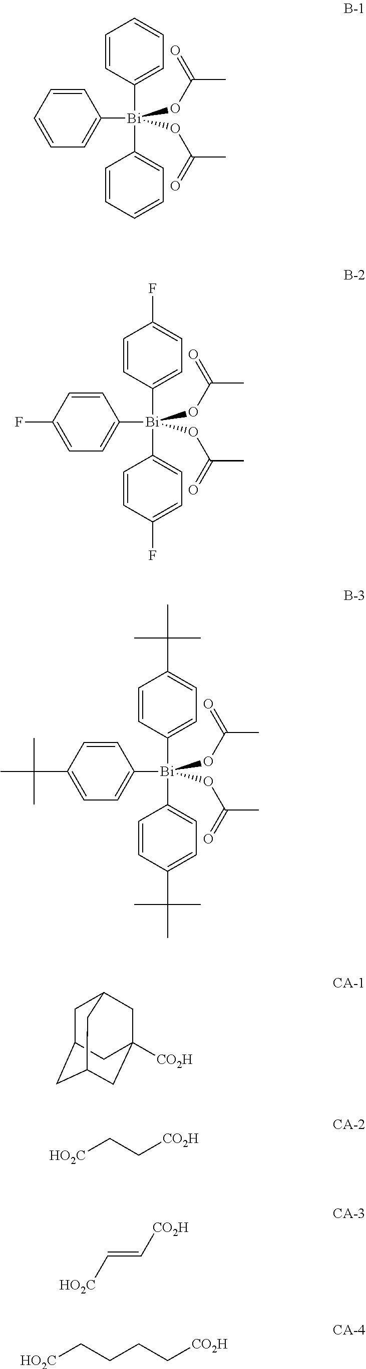

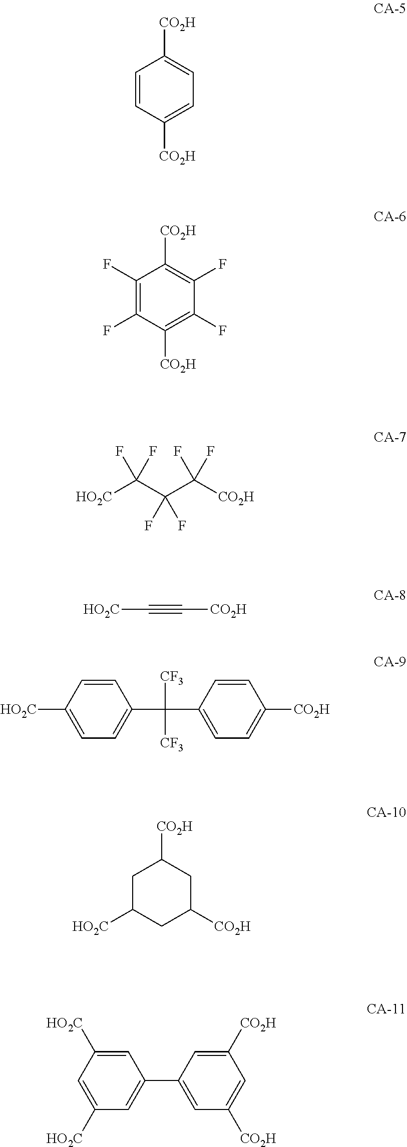

Solvent:
   PGMEA (propylene glycol monomethyl ether acetate)
   HBM (methyl 2-hydroxyisobutyrate)
   GBL (γ-butyrolactone)

In Table 2, the base polymer (P-1), the photoacid generators (PAG-1, PAG-2), and the sensitivity modifiers (Q-1, Q-2) are identified below.

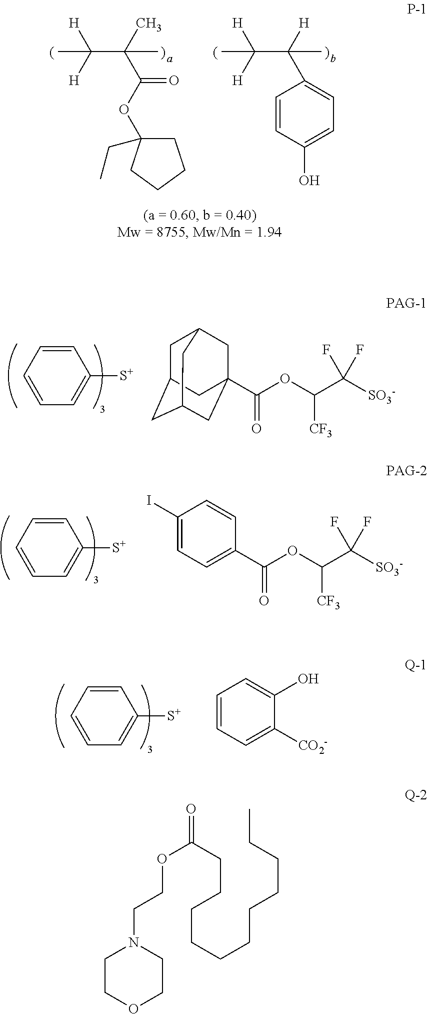

### [2] EUV Lithography Test (Line-and-Space Pattern, Positive Tone Development)

### Examples 2-1 to 2-16 and Comparative Examples 2-1 to 2-3

Each of the resist compositions (R-01 to R-16, CR-01 to CR-03) was spin coated on a silicon substrate having a 20 nm coating of silicon-containing spin-on hard mask SHB-A940 (Shin-Etsu Chemical Co., Ltd., silicon content 43 wt %) and prebaked (PAB) on a hotplate at the temperature shown in Table 3 for 60 seconds to form a resist film of 40 nm thick. Using an EUV scanner NXE3400 (ASML, NA 0.33, σ0.9, 90° dipole illumination), the resist film was exposed to EUV through a mask bearing a 48 nm 1:1 line-and-space (LS) pattern. The resist film was baked (PEB) on a hotplate at the temperature shown in Table 3 for 60 seconds and developed in the developer shown in Table 3 for 30 seconds to form an LS pattern having a space width of 24 nm and a pitch of 48 nm.

The obtained resist pattern was evaluated as follows. The results are shown in Table 3.

### [Evaluation of Sensitivity]

The LS pattern was observed under CD-SEM (CG-6300, Hitachi High-Tech Corporation), and the optimum dose (Eop, mJ/cm²) which provided an LS pattern with a space width of 24 nm and a pitch of 48 nm was determined and reported as sensitivity.

### [Evaluation of LWR]

An LS pattern was formed by exposure in the optimum dose (Eop). The space width was measured under CD-SEM (CG-6300, Hitachi High-Tech Corporation) at longitudinally spaced apart 10 points, from which a 3-fold value (3σ) of the standard deviation (σ) was determined and reported as LWR (nm). A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined under CD-SEM (CG-6300, Hitachi High-Tech Corporation) and reported as maximum resolution (nm). A smaller value indicates a pattern having a better maximum resolution and smaller feature size.

TABLE 3

| | | Resist | PAB/ | | | | Maximum |
|---|---|---|---|---|---|---|---|
| | | com- | PEB | De- | Eop | LWR | resolution |
| | | position | (° C.) | veloper | (mJ/cm²) | (nm) | (nm) |
| Example | 2-1 | R-01 | 120/60 | nBA | 47 | 4.2 | 20 |
| | 2-2 | R-02 | 90/60 | nBA | 54 | 3.6 | 19 |
| | 2-3 | R-03 | 100/60 | nBA | 55 | 3.5 | 19 |
| | 2-4 | R-04 | 120/80 | nBA | 56 | 3.7 | 18 |
| | 2-5 | R-05 | 120/80 | nBA | 58 | 3.8 | 18 |
| | 2-6 | R-06 | 120/60 | nBA | 56 | 3.4 | 16 |
| | 2-7 | R-07 | 110/60 | nBA | 55 | 3.2 | 16 |
| | 2-8 | R-08 | 120/80 | nBA | 57 | 3.5 | 18 |
| | 2-9 | R-09 | 120/80 | nBA | 52 | 3.3 | 15 |
| | 2-10 | R-10 | 120/80 | nBA | 58 | 4.1 | 18 |
| | 2-11 | R-11 | 120/60 | nBA | 58 | 3.7 | 19 |
| | 2-12 | R-12 | 120/80 | nBA | 51 | 3.2 | 15 |
| | 2-13 | R-13 | 120/80 | nBA | 54 | 3.4 | 16 |
| | 2-14 | R-14 | 120/80 | nBA | 56 | 3.7 | 18 |
| | 2-15 | R-15 | 120/80 | nBA | 58 | 3.9 | 19 |
| | 2-16 | R-16 | 120/80 | nBA | 54 | 3.5 | 18 |
| Com- | 2-1 | CR-01 | 105/90 | TMAH | 70 | 4.3 | 22 |
| parative | 2-2 | CR-02 | 105/90 | TMAH | 78 | 4.5 | 22 |
| Example | 2-3 | CR-03 | 105/90 | TMAH | 67 | 4.6 | 24 |

Developer: nBA (butyl acetate)
TMAH (2.38 wt % aqueous tetramethylammonium hydroxide solution)

### [3] EUV Lithography Test (Line-and-Space Pattern, Negative Tone Development)

### Examples 3-1 to 3-16 and Comparative Examples 3-1 to 3-3

Each of the resist compositions (R-01 to R-16, CR-01 to CR-03) was spin coated on a silicon substrate having a 20 nm coating of silicon-containing spin-on hard mask SHB-A940 (Shin-Etsu Chemical Co., Ltd., silicon content 43 wt %) and prebaked (PAB) on a hotplate at the temperature shown in Table 4 for 60 seconds to form a resist film of 40 nm thick. Using an EUV scanner NXE3400 (ASML, NA 0.33, σ0.9, 90° dipole illumination), the resist film was exposed to EUV through a mask bearing a 48 nm 1:1 line-and-space (LS) pattern. The resist film was baked (PEB) on a hotplate at the temperature shown in Table 4 for 60 seconds and developed in the developer shown in Table 4 for 30 seconds to form an LS pattern having a space width of 24 nm and a pitch of 48 nm.

The obtained resist pattern was evaluated as follows. Table 4 shows the results.

### [Evaluation of Sensitivity]

The pattern was observed under CD-SEM (CG-6300, Hitachi High-Tech Corporation), and the optimum dose (Eop, mJ/cm²) which provided an LS pattern with a space width of 24 nm and a pitch of 48 nm was determined and reported as sensitivity.

### [Evaluation of LWR]

An LS pattern was formed by exposure in the optimum dose (Eop). The space width was measured under CD-SEM (CG-6300, Hitachi High-Tech Corporation) at longitudinally spaced apart 10 points, from which a 3-fold value (3σ) of the standard deviation (σ) was determined and reported as LWR (nm). A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined under CD-SEM (CG-6300, Hitachi High-Tech Corporation) and reported as maximum resolution (nm). A smaller value indicates a pattern having a better maximum resolution and smaller feature size.

TABLE 4

| | | Resist | PAB/ | | Eop | | Maximum |
|---|---|---|---|---|---|---|---|
| | | com- | PEB | De- | (mJ/ | LWR | resolution |
| | | position | (° C.) | veloper | cm²) | (nm) | (nm) |
| Example | 3-1 | R-01 | 120/60 | TMAH | 52 | 4.4 | 22 |
| | 3-2 | R-02 | 90/60 | TMAH | 59 | 3.8 | 21 |
| | 3-3 | R-03 | 100/60 | TMAH | 60 | 3.7 | 21 |
| | 3-4 | R-04 | 120/80 | TMAH | 61 | 3.9 | 20 |
| | 3-5 | R-05 | 120/80 | TMAH | 63 | 4 | 20 |
| | 3-6 | R-06 | 120/60 | TMAH | 61 | 3.6 | 18 |
| | 3-7 | R-07 | 110/60 | TMAH | 60 | 3.4 | 18 |
| | 3-8 | R-08 | 120/80 | TMAH | 62 | 3.7 | 20 |
| | 3-9 | R-09 | 120/80 | TMAH | 57 | 3.5 | 17 |
| | 3-10 | R-10 | 120/80 | TMAH | 63 | 4.3 | 20 |
| | 3-11 | R-11 | 120/60 | TMAH | 63 | 3.9 | 21 |
| | 3-12 | R-12 | 120/80 | TMAH | 56 | 3.4 | 17 |
| | 3-13 | R-13 | 120/80 | TMAH | 59 | 3.6 | 18 |
| | 3-14 | R-14 | 120/80 | TMAH | 61 | 3.9 | 20 |
| | 3-15 | R-15 | 120/80 | TMAH | 63 | 4.1 | 21 |
| | 3-16 | R-16 | 120/80 | TMAH | 59 | 3.7 | 20 |
| Comparative | 3-1 | CR-01 | 105/90 | nBA | 75 | 4.5 | 24 |
| Example | 3-2 | CR-02 | 105/90 | nBA | 83 | 4.7 | 24 |
| | 3-3 | CR-03 | 105/90 | nBA | 72 | 4.8 | 24 |

It is evident from Tables 3 and 4 that the resist compositions within the scope of the invention have excellent sensitivity, LWR, and resolution in both positive tone and negative tone development when forming an LS pattern by the EUV lithography.

### [4] EUV Lithography Test (Contact Hole Pattern)

### Examples 4-1 to 4-16 and Comparative Examples 4-1 to 4-3

Each of the resist compositions (R-01 to R-15, CR-01 to CR-03) was spin coated on a silicon substrate having a 20 nm coating of silicon-containing spin-on hard mask SHB-A940 (Shin-Etsu Chemical Co., Ltd., silicon content 43 wt %) and prebaked (PAB) on a hotplate at the temperature shown in Table 5 for 60 seconds to form a resist film of 50 nm thick. Using an EUV scanner NXE3400 (ASML, NA 0.33, σ0.9/0.6, quadrupole illumination), the resist film was exposed to EUV through a mask bearing a hole pattern with a pitch of 64 nm+20% bias (on-wafer size). After exposure, the resist film was baked (PEB) on a hotplate at the temperature shown in Table 5 for 60 seconds and developed in the developer shown in Table 5 for 30 seconds to form a hole pattern having a size of 32 nm.

The obtained resist pattern was evaluated as follows. Table 5 shows the results.

### [Evaluation of Sensitivity]

The contact hole pattern was observed under CD-SEM (CG-6300, Hitachi High-Tech Corporation), and the optimum dose (Eop, mJ/cm²) which provided an LS pattern with a size of 32 nm was determined and reported as sensitivity.

### [Evaluation of CD Uniformity (CDU)]

The size of 50 hole patterns which were printed at Eop was measured, from which a 3-fold value (3σ) of the standard deviation (σ) was computed and reported as CDU (nm). A smaller value of CDU indicates a hole pattern with more uniform hole diameter.

### [Evaluation of Maximum Resolution]

A hole pattern was formed while reducing the exposure dose little by little from the optimum dose (Eop). The hole diameter (nm) which could be resolved was determined under CD-SEM (CG-6300, Hitachi High-Tech Corporation) and reported as maximum resolution (nm). A smaller value indicates a pattern having a better maximum resolution and smaller hole diameter.

TABLE 5

| | | Resist | PAB/ | | Eop | | Maximum |
|---|---|---|---|---|---|---|---|
| | | com- | PEB | De- | (mJ/ | LWR | resolution |
| | | position | (° C.) | veloper | cm²) | (nm) | (nm) |
| Example | 4-1 | R-01 | 120/60 | nBA | 36 | 2.6 | 30 |
| | 4-2 | R-02 | 90/60 | nBA | 39 | 2.8 | 28 |
| | 4-3 | R-03 | 100/60 | nBA | 39 | 2.9 | 28 |
| | 4-4 | R-04 | 120/80 | nBA | 42 | 2.8 | 28 |
| | 4-5 | R-05 | 120/80 | nBA | 42 | 2.8 | 28 |
| | 4-6 | R-06 | 120/60 | nBA | 39 | 2.7 | 26 |
| | 4-7 | R-07 | 110/60 | nBA | 38 | 2.8 | 28 |
| | 4-8 | R-08 | 120/80 | nBA | 41 | 2.9 | 26 |
| | 4-9 | R-09 | 120/80 | nBA | 42 | 2.6 | 26 |
| | 4-10 | R-10 | 120/80 | nBA | 44 | 2.9 | 30 |
| | 4-11 | R-11 | 120/60 | nBA | 44 | 2.8 | 28 |
| | 4-12 | R-12 | 120/80 | nBA | 41 | 2.5 | 26 |
| | 4-13 | R-13 | 120/80 | nBA | 42 | 2.7 | 28 |
| | 4-14 | R-14 | 120/80 | nBA | 39 | 2.8 | 30 |
| | 4-15 | R-15 | 120/80 | nBA | 43 | 2.9 | 30 |
| | 4-16 | R-16 | 120/80 | nBA | 40 | 2.7 | 28 |
| Comparative | 4-1 | R'-01 | 105/90 | TMAH | 48 | 3.6 | 32 |
| Example | 4-2 | R'-02 | 105/90 | TMAH | 45 | 3.8 | 32 |
| | 4-3 | R'-03 | 105/90 | TMAH | 51 | 3.9 | 32 |

It is evident from Table 5 that the resist compositions within the scope of the invention form contact hole patterns having satisfactory sensitivity, CDU, and resolution when processed by the EUV lithography.

Japanese Patent Application No. 2024-038566 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a hypervalent bismuth compound, a carboxylic acid, and a solvent.

2. The resist composition of claim 1 wherein the hypervalent bismuth compound has formula (1): 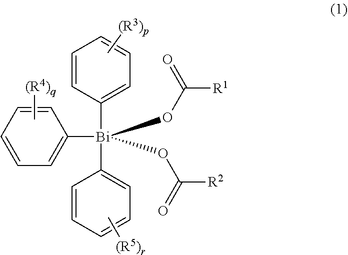
wherein p, q, and r are each independently an integer of 0 to 5,
R¹ and R² are each independently halogen or a C₁-C₁₀ hydrocarbyl group which may contain a heteroatom, R¹ and R² may bond together to form a ring with the carbon atoms to which they are attached and the intervenient atoms, and
R³, R⁴, and R⁵ are each independently halogen or a C₁-C₄₀ hydrocarbyl group which may contain a heteroatom.

3. The resist composition of claim 1 wherein the carboxylic acid has formula (2): 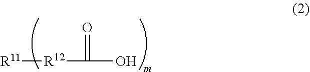
wherein m is an integer of 1 to 4,
R¹¹ is a C₁-C₄₀ m-valent hydrocarbon group or C₂-C₄₀ m-valent heterocyclic group, when m is 2, R¹¹ may be an ether bond, carbonyl group, azo group, thioether bond, carbonate bond, carbamate bond, sulfinyl group or sulfonyl group, and
some or all of the hydrogen atoms in the m-valent hydrocarbon group or m-valent heterocyclic group may be substituted by a heteroatom-containing moiety, and some constituent —CH₂— in the m-valent hydrocarbon group may be substituted by a heteroatom-containing moiety,
R¹² is a single bond or C₁-C₁₀ hydrocarbylene group, and some or all of the hydrogen atoms in the hydrocarbylene group may be substituted by a heteroatom-containing moiety, some constituent —CH₂— in the hydrocarbylene group may be substituted by a heteroatom-containing moiety, and when m is an integer of 2 to 4, a plurality of R¹² may be the same or different.

4. A pattern forming process comprising the steps of applying the resist composition of claim 1 onto a substrate to form a resist film thereon, exposing the resist film to high-energy radiation, and developing the exposed resist film in a developer.

5. The pattern forming process of claim 4 wherein the high-energy radiation is electron beam or extreme ultraviolet.

6. The pattern forming process of claim 4 wherein the developer dissolves an exposed portion and does not dissolve an unexposed portion.

7. The pattern forming process of claim 4 wherein the developer dissolves an unexposed portion and does not dissolve an exposed portion.
